(19) United States
(12) Patent Application Publication
(10) Pub. No.: US 2010/0304084 A1
(43) Pub. Date: Dec. 2, 2010

(54) PROTECTIVE COATINGS WHICH PROVIDE EROSION RESISTANCE, AND RELATED ARTICLES AND METHODS

(75) Inventors: Krishnamurthy Anand, Bangalore (IN); Tamara Jean Muth, Ballston Lake, NY (US); Srinidhi Sampath, Bangalore (IN); Prajina Bhattacharya, Bangalore (IN); Biju Dasan, Bangalore (IN)

Correspondence Address: GENERAL ELECTRIC COMPANY;GLOBAL RESEARCH, ONE RESEARCH CIRCLE, BLDG. K1-3A59, NISKAYUNA, NY, 12309, US

(73) Assignee: GENERAL ELECTRIC COMPANY, SCHENECTADY, NY (US)

(21) Appl. No.: 12/571,178

(22) Filed: Sep. 30, 2009

Related U.S. Application Data
(63) Continuation-in-part of application No. 12/474,535, filed on May 29, 2009.

(51) Int. Cl. B32B 3/00; B05D 1/36; C23C 16/34; C23C 16/32; C23C 14/35; C23C 14/32

(52) U.S. Cl. 428/141; 427/203; 427/569; 204/192.16

(57) ABSTRACT

A coating composition is described, having a first coating layer which includes a metallic matrix in which metal carbide particles are dispersed; and a hard, dense second coating layer disposed over the first coating layer. The second coating layer is formed from a metal nitride-type material, and has an average roughness of less than about 80 micro-inches (Ra). Related articles and processes are also disclosed.

### BACKGROUND OF THE INVENTION

This invention generally relates to coatings for various articles. In some specific embodiments, the invention relates to protective coatings which provide erosion resistance and other benefits to metal articles which are exposed to high temperatures, as well as erosive conditions.

Metal components are used in a wide variety of industrial applications, under a diverse set of operating conditions. In many cases, the components are provided with coatings which impart various characteristics, such as corrosion resistance, heat resistance, oxidation resistance, and wear resistance (i.e., erosion resistance). As one example, the various components of turbine engines, such as steam turbines and gas turbines, are often provided with protective coatings for a number of different purposes. Other examples of articles which require some sort of protective coating include pistons used in internal combustion engines, as well as various parts in other types of machines.

Axial flow fluid turbines represent a good example of sophisticated, large-scale devices which require coatings to protect various components. A primary class of these machines includes the steam turbines, which convert energy stored in high pressure, high temperature steam, into rotational mechanical movement—often used to generate electricity in a power plant. (The steam is usually obtained from an external boiler).

As those skilled in the art understand, steam turbines typically comprise a plurality of turbine blades, or buckets, radially extending and circumferentially mounted on the periphery of a rotor shaft, to form a turbine wheel. Generally, the steam turbine includes a plurality of axially-spaced bucket wheels. The rotor shaft, with associated bucket wheels, is mounted on bearings with the bucket wheels disposed inside an inner shell, which may be, in turn, surrounded by a spaced-apart outer shell. This double shell configuration forms a pressurizable housing in which bucket wheels rotate, and prevents potentially damaging thermal gradients. The bucket wheels are typically disposed between corresponding stationary nozzle diaphragms, which are formed by an array of stationary, aerodynamically-configured partitions. The partitions are substantially radially disposed between and fixedly retained by a pair of concentric diaphragm rings, which circumferentially surround the rotor. These partitions are typically referred to as “nozzle partitions”, and the spaces between the partitions are usually referred to as “nozzles”.

As steam flows through the interior cavity of the pressurizable inner shell, it passes through and co-acts with alternately-disposed stationary nozzle partitions and rotatable turbine bucket wheels, to produce rotational movement of the rotor shaft. The combination of a pair of diaphragm rings with their associated partitions, and the cooperating row of downstream buckets, is generally referred to as a “stage”, stages being numbered sequentially in the direction of steam flow starting from the steam input region. These concepts are generally well known in the turbine art.

Various sections of the steam turbine, e.g., regions on the buckets themselves, as well as the diaphragm partitions, have been found to be susceptible to solid particle erosion, also referred to as “SPE”. It is believed that most of the erosive particles result from the exfoliation of an oxide film from the steam-side of boiler tubes and other steam conduits. The oxide film appears to be primarily composed of magnetite, Fe₃O₄. In the case of some of the commercial steam turbines, the erosion problem can sometimes occur when steam inlet temperatures are at least about 900° F. (482° C.); and the turbine has been in service for a number of years. (However, many factors are involved in predicting when a certain degree of erosion might occur for a given turbine).

Different ways of addressing the erosion problem and related issues have been described and implemented over the years. As one example, Sumner et al describe improved nozzle configurations for steam turbines, in U.S. Pat. No. 4,776,765. The novel configurations involve the use of an aerodynamically shaped suction surface, and an additional protective surface, such as an erosion-resistant coating. Other references generally related to turbines also describe the use of protective coatings, e.g., U.S. Pat. No. 7,186,092 (Bruce et al).

Protective coatings have been applied to various articles by vacuum coating techniques, such as physical vapor deposition (PVD). In some cases, the PVD coatings provide very good erosion resistance to the underlying article. However, these coatings are often very thin, e.g., less than about 50 microns (0.05 mm). Moreover, the PVD coatings may have thermal expansion and contraction characteristics which are quite different from those of an underlying metal substrate. Solid erosive particles which contact the coating may initiate the formation of an elastic-plastic indentation zone through the coating, which may, in turn, cause the substrate to deform plastically. The differential deformation may cause the PVD coatings to peel or otherwise degrade, thereby leaving the substrate exposed to much greater erosion from the solid particles.

Moreover, research is continuing on increasing the operating temperatures and service life of high-temperature machinery like the multi-stage steam turbines. The erosion-resistant coatings which are presently available may not always be able to adequately protect the underlying substrates, under the more-rigorous service environment. Erosion damage in a large steam turbine can change the geometry of the steam path, thereby reducing turbine and power-plant efficiency. Moreover, valves, buckets, and other components in the steam turbine may have to be replaced or refurbished after shorter service periods, and this may also shorten the practical operating life of the turbine.

With these considerations in mind, new protective coatings for high-temperature articles would be welcome in the art. The coatings should provide good resistance to erosion and other types of environmental attack. They should also adhere relatively well to the underlying substrate, and should be capable of application in economical fashion. The coatings should also maintain a desirable level of other properties, such as hardness, impact strength, a selected surface-finish, and high-temperature fatigue strength.

### SUMMARY OF THE INVENTION

One embodiment of the invention is directed to a coating composition, comprising:

(a) a first coating layer, comprising a metallic matrix in which metal carbide particles are dispersed; and

(b) a hard, dense second coating layer disposed over the first coating layer, comprising a metal nitride material, and having an average roughness of less than about 80 micro-inches (Ra).

Another embodiment of the invention is directed to an article which is at least partially covered by the coating composition mentioned above, and described in further detail in this document. (The coating composition is sometimes referred to as a “bi-layer” coating or a “combination” coating).

A method for the formation of a protective coating on a metallic substrate constitutes another embodiment of the invention. The method comprises the following steps:
(I) applying a first coating layer on the substrate by a technique selected from high velocity oxy-fuel (HVOF) or high-velocity air-fuel (HVAF), wherein the first coating material comprises a metallic matrix in which metal carbide particles are dispersed; and
(II) applying a second coating layer over the first coating layer by a vapor deposition technique or by suspension plasma spraying, wherein the second coating layer comprises a metal nitride material.

### BRIEF DESCRIPTION OF THE DRAWINGS

FIG. 1 is a simplified, fragmentary view of a coating system according to some embodiments of this invention.

### DETAILED DESCRIPTION OF THE INVENTION

All amounts set forth herein are provided in weight percent (wt %), unless otherwise indicated. The disclosed compositional ranges are inclusive and combinable. For example, ranges of “up to about 25 wt %”, or, more specifically, “about 5 wt % to about 20 wt %”, are inclusive of the endpoints and all intermediate values of the ranges. Furthermore, the terms “first,” “second,” and the like, herein do not denote any order, quantity, or importance, but rather are used to distinguish one element from another. The terms “a” and “an” herein do not denote a limitation of quantity, but rather denote the presence of at least one of the referenced items. The modifier “about”, used in connection with a quantity, is inclusive of the stated value, and has the meaning dictated by context, (e.g., includes the degree of error associated with measurement of the particular quantity). The suffix “(s)” as used herein is intended to include both the singular and the plural of the term that it modifies, thereby including one or more of that term (e.g., “the refractory element(s)” may include one or more refractory elements). Reference throughout the specification to “one embodiment”, “another embodiment”, “an embodiment”, and so forth, means that a particular element (e.g., feature, structure, and/or characteristic) described in connection with the embodiment is included in at least one embodiment described herein, and may or may not be present in other embodiments. In addition, it is to be understood that the described inventive features may be combined in any suitable manner in the various embodiments.

As mentioned above, the present invention includes multiple coating layers. The first coating layer comprises a metallic matrix in which metal carbide particles are dispersed. Various metallic matrixes may be used for the first layer. In one embodiment, the matrix comprises nickel-chromium. For this embodiment, the proportion of nickel and chromium in the matrix can vary to some degree, depending in large part on the intended end use of the coating composition. In some specific embodiments for the nickel-chromium matrix, the amount of nickel in the first coating layer is in the range of about 14% to about 22%, based on the total weight of the material in the first coating layer, and preferably, in the range of about 14% to about 18%. Moreover, in some specific embodiments, the amount of chromium in the first coating layer is in the range of about 68% to about 78%, and preferably, in the range of about 72% to about 76%. The specific level of nickel and chromium for this embodiment can be modified to enhance selected coating properties, such as ductility and hardness. Useful, general information regarding these types of coatings is also provided in U.S. Pat. Nos. 6,071,324 (Laul et al) and 4,606,948 (Hajmrle et al), both of which are incorporated herein by reference.

In another embodiment, the matrix comprises an alloy having the formula MCrAlX. In this formula, “M” can be iron, cobalt, nickel, or any combination thereof, and “X” is a rare earth element. As used herein, the term “rare earth element” can refer to a single rare earth element, or a combination of rare earth elements. Examples include lanthanum, cerium, praseodymium, neodymium, samarium, europium, gadolinium, terbium, dysprosium, holmium, erbium, thulium, ytterbium, and lutetium, as well as scandium or yttrium. In some specific embodiments, the rare earth element is yttrium, hafnium, lanthanum, cerium, or scandium, or some combination thereof. Yttrium is often the most preferred rare earth element.

The MCrAlX materials are described in a number of references. Non-limiting examples include U.S. Pat. Nos. 6,497,758; 6,447,854; and 6,123,997, all of which are incorporated herein by reference. Some of the specific alloys of the MCrAlX-type have a broad composition (in weight percent) of about 17% to about 23% chromium; about 4% to about 13% aluminum; and about 0.1% to about 2% yttrium, with M constituting the balance. In some embodiments, M is a mixture of nickel and cobalt, wherein the ratio of nickel to cobalt is in the range of about 10:90 to about 90:10, by weight. However, it should be noted that the specific alloy composition for MCrAlX can vary significantly (e.g., with higher levels of chromium), and will depend in large part on the end use intended for the coating material.

A variety of metal carbides can be dispersed within the metallic matrix. Examples include chromium carbide, tantalum carbide, hafnium carbide, niobium carbide, vanadium carbide, and combinations thereof. In some preferred embodiments, the metal carbide comprises chromium carbide. For example, the total carbide content in the first coating layer material may comprise at least about 65% by weight chromium carbide, and preferably, at least about 75% by weight chromium carbide. The chromium carbides can be present in a variety of forms. Examples include Cr₃C₂, Cr₇C₃, Cr₂₃C₆, and mixtures thereof. (While chromium carbides are exemplified below, it should be understood that the scope of the invention is meant to include the other carbides as well, with or without the chromium analogue).

Particles of the metal carbides such as chromium carbide are often characterized by a substantially orthorhombic crystal structure. Moreover, in some specific embodiments, the average particle size of the metal carbide particles is in the range of about 5 microns to about 10 microns, although in some instances, larger-sized particles may be used. As described below, the optimum particle size will be dependent in part on the technique used to form the first coating layer.

As may be apparent from above, in many specific embodiments, the chromium in the first layer material is present in different forms. A first portion of the chromium is usually alloyed with the metal(s) in the metallic matrix, such as nickel, and a second portion is combined with carbon in the carbide. Moreover, the chromium carbide material can be considered to be a “precipitate” which is distributed substantially uniformly within the alloy matrix. Methods for preparing the first coating layer material are generally known in the art, and they depend on the specific constituents; the method in which the material is applied to an article; and the ultimate end use for the article.

In most embodiments (and especially in the case of a chromium-based metal carbide), the amount of the matrix within the overall composition is controlled, so as to optimize the property-balance between ductility and hardness. As an example, greater proportions of the matrix material will often enhance ductility, but may detract from coating hardness. Moreover, while lower proportions of the matrix material can ensure coating hardness, very low levels can make the coating brittle.

Usually, the matrix is present at a level in the range of about 7% by weight to about 35% by weight, based on the weight of the entire composition for the first coating layer. In some instances, a preferred level for the matrix is about 18% by weight to about 22% by weight. In general, the contemplated end use for the coating composition will serve as the guideline for the most appropriate amount of alloy matrix.

The first coating layer is usually applied to a surface of an article by a thermal spray technique. In some specific embodiments, high velocity oxygen fuel (HVOF) or high velocity air fuel (HVAF) techniques are employed, and general details regarding each technique are known in the art. As one specific illustration, HVOF techniques are described in U.S. Pat. Nos. 5,508,097 and 5,527,591, both incorporated herein by reference. HVOF is a continuous combustion process in which the powder is injected into the jet stream of a spray gun at very high speeds.

Those of ordinary skill in the art are familiar with various HVOF details, such as the selection of primary gasses, secondary gasses (if used), and cooling gasses; gas flow rates; power levels; coating particle size, and the like. HVOF types of powder spray guns are typified in U.S. Pat. Nos. 4,416,421 and 4,865,252. This type of gun has a combustion chamber with a high pressure combustion effluent directed through a nozzle or open channel. Powder is fed into the nozzle chamber to be heated and propelled by the combustion effluent. Methods of spraying various materials with high velocity oxygen-fuel guns are taught in U.S. Pat. Nos. 4,999,225 and 5,006,321.

The HVAF process is similar to HVOF, i.e., being based on a continuous combustion process in which the powder is injected into the jet stream of a spray gun at very high speeds, and directed to the substrate. HVAF processes are described, for example, in U.S. Pat. No. 7,431,566 (Gray et al), which is incorporated herein by reference. The HVAF process utilizes a fuel such as kerosene, propane, propylene, or the like, that is combusted with air. This is in contrast to the HVOF technique, wherein oxygen combustion occurs. Thus, the thermally-sprayed particulate feedstock in the HVAF process is typically exposed to a lower temperature as compared to the HVOF process. However, both techniques have advantages and some drawbacks, and one of skill in the art will be able to determine the most appropriate technique for a given situation, based on the teachings herein.

The first layer powder materials may be prepared by conventional methods, in preparation for the thermal spray technique such as HVAF or HVOF. As an example, spray drying techniques can be used, sometimes accompanied by subsequent heating steps. These techniques are described in U.S. Pat. Nos. 3,617,358 and 3,974,245, which are incorporated herein by reference. In some exemplary embodiments, the spray powders are formed by blending the carbide and metal constituents. The blended constituents can be agglomerated, sintered, and densified in a suitable atmosphere, e.g., a vacuum, or an inert atmosphere, and then crushed and screened to provide the desired powder size. U.S. Pat. No. 5,419,976 (Dulin) provides some general guidance as well, and is incorporated herein by reference. As another example, the spray powder can be formed by rapid solidification from a melt, as described in the reference mentioned above, U.S. Pat. No. 6,071,324. Solidification can be achieved by conventional atomization, e.g., inert gas atomization.

Those skilled in the art are familiar with other details regarding the deposition process for the first coating layer, e.g., substrate preparation, often by grit-blasting and the like. The layer applied by the thermal spray technique is usually very dense (i.e., minimum porosity), and substantially non-oxidized. In some specific embodiments, the first layer coating has a porosity less than about 5%, and more often, less than about 2%.

The thickness of the first coating layer will depend on many of the factors described previously. A primary consideration relates to the type and size of erodant particles which will be coming into contact with the coating system. Another key consideration involves the type and thickness of the second coating layer, discussed below. In some embodiments, the first coating layer thickness will be in the range of about 5 mils (127 microns) to about 15 mils (381 microns). In the case of many turbine component applications, the thickness of the first coating layer will be at least about 8 mils (203 microns). For various steam turbine components, e.g., buckets in the high pressure- and reheat inlet stages of the turbine, the thickness will often be in the range of about 8 mils (203 microns) to about 11 mils (280 microns).

In most embodiments, the composition of the first layer undergoes a strengthening or “hardening” phenomenon—especially at elevated temperatures, and over a period of time. Usually, strengthening occurs because of the precipitation of various metal carbides within the metallic matrix, as the coating attains its equilibrium microstructure. The specific time- and temperature-conditions under which strengthening will occur depend on various factors, such as the specific composition (matrix and dispersed particles) of the layer, as well as the composition of the second coating layer.

In some instances, significant strengthening may occur when the coating is exposed to temperatures which average at least about 850° C., for at least about 200 hours. However, this regimen can vary considerably, e.g., over the course of 6 months or more. (Higher exposure temperatures may compensate for shorter time periods, while longer time periods may compensate for lower exposure temperatures). This strengthening phenomenon, within the context of the overall coating system, can be extremely advantageous for protective coating performance, as further discussed below. (It should be understood that the heat treatment for the first layer could be carried out directly, e.g., in a suitable furnace, or could be effected “in-situ”, i.e., by way of elevated temperatures which occur during operation of the part, e.g., a turbine. A combination of the direct heat treatment and the in-situ heat treatment is also possible).

As formed, the first coating layer can sometimes be relatively rough. The specific texture will depend in part on the particular deposition apparatus. Very often, the surface of the first coating has a roughness (Ra) of about 100 micro-inches to about 400 micro-inches. Thus, in preferred embodiments, the surface should be treated to decrease the roughness; and this appears to enhance the erosion resistance of the overall coating system in many cases. The surface treatment should result in a “smoothening” of the surface, to a roughness less than about 100 micro-inches, and in some specific embodiments, less than about 60 micro-inches.

A number of techniques can be used to smoothen the surface of the first coating layer. Examples include grinding, tumbling, sanding, and polishing operations. Those skilled in the art will be able to select the most appropriate technique (or combination of techniques), to provide the desired surface profile, without adversely affecting the layer. The most appropriate surface profile for a given situation depends on various factors, including the composition of the second layer, described below. Moreover, in some instances, a first coating layer which is excessively smooth may prevent adequate adhesion of the overlying second layer. Those skilled in the art can readily determine the optimum surface profile for the first coating layer, based on the teachings herein.

As mentioned above, a hard, dense second coating layer is disposed over the first coating layer. The second coating layer comprises a metal nitride material. These materials are generally known in the art, and described, for example, in the patent to Bruce et al (mentioned above), which is incorporated herein by reference. Many of the materials are also described in U.S. Pat. Nos. 4,904,528 (Gupta et al), and 4,839,245 (Sue et al), which are also incorporated herein by reference.

Non-limiting examples of the metal nitride materials for the second coating layer include titanium nitride (TiN), or a mixture of titanium nitride and titanium-aluminum nitride. Combinations of at least two of titanium nitride, zirconium nitride, chromium nitride, aluminum nitride, titanium carbonitride (TiCN), and titanium-aluminum nitride, may also be possible. In another embodiment, the second coating layer may comprise particles of one or more metal nitrides such as TiN or TiCN, which are dispersed in a silicon carbide (SiC) matrix or a silicon carbonitride (SiCN) matrix. (These matrices are usually amorphous). In this embodiment, the particles are often very small, e.g., nanoparticles, with an average particle size less than about 50 nanometers. The second coating layer may also contain titanium metal.

In some embodiments, the second coating layer comprises two or more sub-layers. The use of multiple sub-layers may be beneficial for overall adhesion to the underlying first coating layer. Moreover, the sequence and content of the sub-layers may enhance matching of the thermal expansion characteristics (e.g., CTE) of the second coating layer with the first layer. As one non-limiting example, the second coating layer can comprise alternating layers of titanium metal, and one of either titanium nitride or titanium-aluminum nitride. Since the titanium layer can serve to relieve the stress of the more brittle titanium nitride layer, it is possible to increase the thickness of the overall coating. Many other variations on coating sequence may be possible.

The second coating layer of the present invention is applied over the first coating layer by a vapor deposition technique or by suspension plasma spraying. Many of the vapor deposition processes are referred to as “vacuum coating” techniques. In general, the techniques involve the deposition of relatively thin films, by the condensation of a vaporized form of the coating material onto a substrate. These techniques are generally known in the art. See, for example, the “Handbook of Thin Film Process Technology”, by Glocker, David A., and S. Ismat Shah (editors), Bristol, U.K.: Institute of Physics Pub, 2002; “Physical Vapor Deposition of Thin Films”, by John Mahan; New York, John Wiley & Sons, 2000; and the “Handbook of Physical Vapor Deposition (PVD) Processing: Film Formation, Adhesion, Surface Preparation and Contamination Control”, by D. M. Mattox, Westwood, N.J.: Noyes Publications, 1998; and U.S. Pat. No. 5,609,921 (Gitzhofer et al, “Suspension Plasma Spray”). Each of these references is incorporated herein by reference.

Non-limiting examples of the vapor deposition techniques include physical vapor deposition (PVD), cathodic arc deposition, magnetic sputtering (also sometimes referred to as “magnetron sputtering”), and electron beam physical vapor deposition (EBPVD). Choice of a particular technique (i.e., one of the vapor deposition techniques or a suspension plasma spray technique) will depend on a variety of considerations, such as coating composition; first layer composition; and equipment availability.

In many cases, cathodic arc techniques and magnetron sputtering techniques are sometimes of special interest. (Both can be considered part of the broad category of PVD). Cathodic arc deposition is a technique in which an electric arc is used to vaporize material from a cathode target. The vaporized material then condenses on a substrate, forming a thin film. Many references describe aspects of this technique. Non-limiting examples include U.S. Pat. Nos. 5,580,429 (Chan et al); 6,026,763 (Kim et al); 6,409,898 (Weaver et al); 6,436,254 (Weaver et al); and 6,608,432 (Weaver et al), which are all incorporated herein by reference.

A magnetron sputtering technique is a specialized form of sputter deposition, and is known in the art. In general, sputter deposition is carried out in an evacuated chamber, by sputtering a material from a target, which is then deposited onto a selected substrate. Usually, sputtering utilizes an inert gas such as argon. In the case of magnetron sputtering, magnets are usually placed behind, and sometimes, at the sides of the target. The magnets capture electrons which would otherwise escape during the deposition process, and confine them to the immediate vicinity of the target, thereby increasing deposition rates. Instructive, non-limiting references related to magnetron sputtering are U.S. Pat. Nos. 6,635,155 (Miyamura et al) and 6,641,701 (Tepman), both incorporated herein by reference.

The thickness of the second coating layer will also depend on many of the factors described previously, including the particular deposition technique which is employed; and the article which is being coated. Usually, the second coating layer is relatively thin, e.g. having a thickness which is less than about 20% of the thickness of the first coating layer, and in some instances, less than about 10% of the thickness of the first layer. In some embodiments, the second layer thickness will be in the range of about 0.5 micron to about 100 microns. In the case of many turbine component applications, the thickness of the second coating layer will often be at least about 1 micron. For various steam turbine components, e.g., buckets in the high pressure- and reheat inlet stages of the turbine, the thickness will often be in the range of about 10 microns to about 50 microns.

As mentioned above, the second coating layer is very dense. The porosity of the coating is usually less than about 0.5%, and in some instances, less than about 0.1% (almost no detectable porosity). Moreover, the coating is very hard, usually being characterized by a Vickers hardness (“HV”) of at least about 2500, and in some cases, at least about 3500. Furthermore, as also described previously, the surface of the second coating is usually very smooth, e.g., having an average roughness (Ra) of less than about 80 micro-inches, and preferably, less than about 70 micro-inches. In some instances, the second coating layer may have an average roughness of about 50 micro-inches or less. (The roughness of the second coating depends in part on the roughness or “profile” of the underlying, first coating layer). These features of the second coating layer provide a high degree of erosion resistance to the overall coating system.

As alluded to previously, there are special advantages to the multi-layer coating system of this invention. When the coating system is applied to a high-temperature part such as a steam turbine bucket, the hard, dense second coating layer provides excellent erosion resistance during at least a portion of the operating period of the steam turbine. Meanwhile, at operating temperatures which may average in the range of about 900° F. (482° C.) to about 1200° F. (649° C.), the underlying, first coating layer continues to strengthen, e.g., by way of the carbide-precipitation mechanism discussed previously. Thus, by the time the relatively thin second coating layer wears down, the first coating layer has often attained a level of strength and hardness through at least a substantial portion of its depth. This allows the first coating layer to provide additional erosion resistance to the turbine part, during the remainder of the operating period of the part. In this manner, the overall service life of the part can be considerably extended, which can in turn result in numerous advantages in a commercial setting.

As mentioned previously, another embodiment of this invention is directed to an article which is at least partially covered by the coating composition described herein, i.e., the coating system which comprises the first coating layer and the second coating layer.

The article (i.e., the substrate being protected by the coating composition) can be formed from a variety of materials, e.g., metals and metal alloys; as well as ceramic or plastic materials, or combinations of any of these materials. Non-limiting examples of the metallic materials include iron, steel alloys, titanium alloys, nickel alloys, and cobalt alloys.

Non-limiting examples of such articles include turbine engines, such as steam turbines, gas turbines; turboexpanders (e.g., for oil refinery equipment); compressor components (e.g., high-pressure compressor blades); pistons used in internal combustion engines, cutting tools which can be exposed to high temperatures, and the like. In short, any part which is used at elevated temperatures, and which requires protection from erosion resistance, may constitute the article of this invention. Some specific examples of turbine components (e.g., steam turbine components) include vanes, blades, buckets, stators, nozzle diaphragms, and the like.

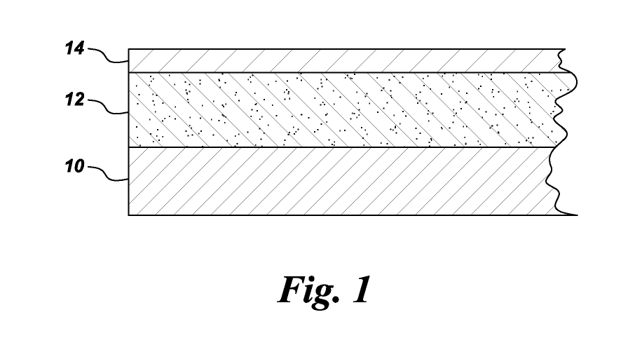

FIG. 1 is a simplified, fragmentary view of a coating system according to some embodiments of this invention. (The relative thickness of the layers in the FIGURE is not meant to be representative of actual thicknesses; the FIGURE is depicted for ease-of-viewing). Substrate 10 can represent many types of articles, as described previously. Layer 12 is the first coating layer, comprising the metallic matrix in which metal carbide particles are dispersed. Layer 14 represents the hard, dense, second coating layer, formed at least in part from various types of metal nitride materials.

### EXAMPLES

The example presented below is intended to be merely illustrative, and should not be construed to be any sort of limitation on the scope of the claimed invention.

Coating materials were applied to Inconel®625 (nickel-based alloy) substrates. A first set of samples were formed by applying a first layer of a chrome-carbide nickel-chrome coating material to the substrate, by way of an HVOF process. The coating material was a commercial powder from Sulzer Metco® Corporation, and contained chromium carbide (Cr₃C₂), dispersed in 80% nickel/20% chrome (i.e., the matrix). The average powder particle size was about 5-10 microns.

A METCO DJ2600 HVOF gun was used to apply the first layer. The oxidizing gas was oxygen, with a flow rate of about 32 FMR (flow meter reading). The fuel gas was hydrogen, with a flow rate of about 64 FMR (at 140 psi). A carrier gas was also used, with a flow rate of about 28.5 scfh, at 150 psi. The powder was sprayed at a rate of 5 lb/hour (2.27 kg/hour), at a distance of about 10 inches (25.4 cm) from the substrate, at a surface speed of about 500 mm/second.

The thickness of the coating was about 10 mils (254 microns). The average roughness of the first layer, as sprayed, was about 239 micro-inches (Ra). The surface was then polished by hand-grinding, to smoothen it to an average roughness of about 36 micro-inches (Ra).

A second layer was then applied over the first layer. For some of the samples, the second layer was applied by cathodic arc deposition. A series of sub-layers constituted the second layer, with a layer of titanium metal being applied first, to a thickness of about 1 micron. This layer was followed by alternating layers of titanium nitride and titanium-aluminum-nitride, with each layer having an average thickness of about 4-5 microns. A total of about 6 layers were applied to each sample, for a total thickness (second layer) of about 25-30 microns. The average roughness of the cathodic arc-deposited layer, after all sub-layers were deposited, was about 101 micro-inches (Ra).

Another set of samples were prepared by applying the second layer over the HVOF-applied first layer, using magnetron sputtering. In this case, the second layer coating composition consisted of relatively thick layers of titanium, silicon, carbon, and nitrogen (Ti—Si—C—N) nanocrystals, 4-7 nanometers thick, in a matrix of amorphous, glass-like silicon carbonitride. The overall thickness was at least about 50 microns, and the roughness, as measured on the top layer, was about 38 micron-inches (Ra). Other details regarding this type of coating process for the second layer are provided by Ronghua Wei et al, “Super Hard, Very Tough”, Technology Today®, Spring 2008 (See also website: http://www.swri.org/3pubs/ttoday/Spring08/Super.htm).

For all of the samples, the overall thickness of the bi-layer coating was about 270-300 microns. Test coupons (3 inch×1 inch (7.6 cm×2.5 cm), 3 mm thickness) from the bi-layer composite were used for erosion tests. A high-temperature air jet erosion test was employed, using magnetite particles as the erosive agent. (The average size of the magnetite particles for this example was about 50 microns). The magnetite particles are blown through a 5 mm (diameter) nozzle, and become heated from a heated air source, as they impact the surface of the coupons, at an angle of about 30 degrees. The magnetite “dosage” was 400 grams, i.e., magnetite flow for 400 grams over the course of 2 hours, at a rate of about 3 grams per minute.

Samples outside the scope of this invention (“comparative samples”) were evaluated along with the samples described above. One of the samples outside the scope of the invention was a single coating of the same commercial material mentioned above, i.e. Sulzer Metco® chromium carbide/nickel-chrome material. The coating was applied to an Inconel®625 substrate by the same, general HVOF process described above, to a thickness of about 250 microns.

After erosion tests were carried out on the samples, they were evaluated from various perspectives, including cross-sectional inspection. (The magnetite particles are relatively soft, and may also transform, at least partially, into hematite at the testing temperatures).

The comparative samples, with an average, single-coating depth of about 250 microns, exhibited erosion to a depth of about 100 microns. In contrast, samples with the bi-layer coating of this invention showed very little erosion. (An in-profile inspection of the samples appeared to show about a 6-micron decrease in thickness, indicating minimal erosion, although cross-sectional analysis did not appear to even show that level of erosion. There was also some minimal cracking present, which may have been due to the soft texture of the magnetite/hematite.

The present invention has been described in terms of some specific embodiments. They are intended for illustration only, and should not be construed as being limiting in any way. Thus, it should be understood that modifications can be made thereto, which are within the scope of the invention and the appended claims. Furthermore, all of the patents, patent applications, articles, and texts which are mentioned above are incorporated herein by reference.

What is claimed:

1. A coating composition, comprising:
(a) a first coating layer, comprising a metallic matrix in which metal carbide particles are dispersed; and
(b) a hard, dense second coating layer disposed over the first coating layer, comprising a metal nitride material, and having an average roughness of less than about 80 micro-inches (Ra).

2. The coating composition of claim 1, wherein the metallic matrix in the first coating layer comprises a nickel-chromium matrix.

3. The coating composition of claim 2, wherein the amount of nickel in the first coating layer is in the range of about 14% to about 22%, based on the total weight of the material in the first coating layer.

4. The coating composition of claim 2, wherein the amount of chromium in the first coating layer is in the range of about 68% to about 78%, based on the total weight of the material in the first coating layer.

5. The coating composition of claim 1, wherein the metallic matrix comprises an alloy having the formula MCrAlX, where M is selected from the group consisting of iron, cobalt, nickel, or combinations thereof, and “X” is at least one rare earth element.

6. The coating composition of claim 5, wherein M is nickel.

7. The coating composition of claim 5, wherein X is selected from the group consisting of yttrium, hafnium, lanthanum, cerium, scandium, and combinations thereof.

8. The coating composition of claim 5, wherein the metallic matrix comprises NiCrAlY.

9. The coating composition of claim 1, wherein the metal carbide is selected from the group consisting of chromium carbide, tantalum carbide, hafnium carbide, niobium carbide, vanadium carbide, and combinations thereof.

10. The coating composition of claim 1, wherein the metal carbide comprises chromium carbide.

11. The coating composition of claim 10, wherein the chromium carbide comprises a material selected from the group consisting of Cr₃C₂, Cr₇C₃, Cr₂₃C₆, and mixtures thereof.

12. The coating composition of claim 10, wherein the metal carbide particles are characterized by a substantially orthorhombic crystal structure.

13. The coating composition of claim 1, wherein the average particle size of the metal carbide particles is in the range of about 5 microns to about 10 microns.

14. The coating composition of claim 1, wherein the metallic matrix is present at a level in the range of about 7% by weight to about 35% by weight, based on the total weight of the first coating layer.

15. The coating composition of claim 1, wherein the second coating layer comprises
I) titanium nitride; or
II) a mixture of at least two of titanium nitride, zirconium nitride, chromium nitride, aluminum nitride, titanium carbonitride, and titanium-aluminum nitride; or
III) metal nitride particles dispersed in an amorphous silicon carbide matrix.

16. The coating composition of claim 15, wherein the second coating layer further comprises titanium metal.

17. The coating composition of claim 1, wherein the second coating layer comprises two or more sub-layers.

18. The coating composition of claim 17, wherein the second coating layer comprises alternating layers of titanium metal and one of either titanium nitride or titanium-aluminum nitride.

19. The coating composition of claim 1, wherein the second coating layer has a porosity of less than about 0.5%.

20. The coating composition of claim 1, wherein the second coating layer is characterized by a hardness of at least about HV/2500, as measured by Vickers hardness.

21. The coating composition of claim 1, wherein the second coating layer (b) has a thickness which is less than about 20% of the thickness of the first coating layer (a).

22. An article which is at least partially covered by the coating composition of claim 1.

23. The article of claim 22, wherein the first coating layer is applied over a surface of the article by a technique selected from high velocity oxy-fuel (HVOF) or high-velocity air-fuel (HVAF).

24. The article of claim 22, wherein the second coating layer is applied over the first coating layer by a vapor deposition technique, or by suspension plasma spraying.

25. The article of claim 24, wherein the vapor deposition technique is selected from the group consisting of physical vapor deposition (PVD), cathodic arc deposition, magnetron sputtering, and electron beam physical vapor deposition (EBPVD).

26. A turbine component, at least partially covered by the coating composition of claim 1.

27. The turbine component of claim 26, in the form of at least one of a vane, blade, bucket, stator, and nozzle diaphragm.

28. The turbine component of claim 26, formed of at least one material selected from the group consisting of iron, steel alloys, titanium alloys, nickel alloys, and cobalt alloys.

29. A steam turbine component according to claim 26.

30. A method for the formation of a protective coating on a metallic substrate, comprising the following steps:
(I) applying a first coating layer on the substrate by a technique selected from high velocity oxy-fuel (HVOF) or high-velocity air-fuel (HVAF), wherein the first coating material comprises a metallic matrix in which metal carbide particles are dispersed; and
(II) applying a second coating layer over the first coating layer by a vapor deposition technique or by suspension plasma spraying, wherein the second coating layer comprises a metal nitride material.

31. The method of claim 30, wherein the metallic matrix comprises nickel-chromium or an alloy having the formula MCrAlX, where M is selected from the group consisting of iron, cobalt, nickel, or combinations thereof, and X is at least one rare earth element.

32. The method of claim 30, wherein the second coating layer is applied as two or more sub-layers.

33. The method of claim 32, wherein the second coating layer is applied as alternating layers of titanium metal and one of either titanium nitride or titanium-aluminum nitride.

34. The method of claim 30, wherein a surface treatment step is carried out on the first coating layer, prior to step (II), to reduce roughness (Ra) in the surface to a level less than about 100 micro-inches.
